(19) United States
(12) Patent Application Publication
(10) Pub. No.: US 2016/0192481 A1
(43) Pub. Date: Jun. 30, 2016

(54) IMPLEMENTING CONFORMAL COATING COMPOSITION FOR HIGH CURRENT CIRCUIT APPLICATIONS

(71) Applicant: International Business Machines Corporation, Armonk, NY (US)

(72) Inventors: Dylan J. Boday, Tucson, AZ (US); Joseph Kuczynski, North Port, FL (US); Jason T. Wertz, Pleasant Valley, NY (US); Jing Zhang, Poughkeesie, NY (US)

(21) Appl. No.: 14/698,488

(22) Filed: Apr. 28, 2015

Related U.S. Application Data
(63) Continuation of application No. 14/584,077, filed on Dec. 29, 2014.

(51) Int. Cl. H05K 1/03; H05K 3/46; H05K 3/00

(52) U.S. Cl. CPC H05K 1/0373; H05K 3/0091; H05K 3/46

(57) ABSTRACT

A method and structure are provided for implementing a conformal coating composition for high current applications. A copper particulate filler material layer is added over a standard conformal coating layer of a circuit component. The added layer aids in dispersing the heat away from the circuit component. The copper particulate filler material reacts with sulfur bearing gasses and prevents corrosive agents from reacting with the underlying component metallurgy, thus extending the product life.

This application is a continuation application of Ser. No. 14/584,077 filed Dec. 29, 2014.

### FIELD OF THE INVENTION

The present invention relates generally to the data processing field, and more particularly, relates to a method and structure for implementing a conformal coating composition for high current applications.

### DESCRIPTION OF THE RELATED ART

The electronics industry designs and tests hardware (HW) to be able to withstand typical indoor air environments. Recently, several HW failures have occurred in geographies known to exhibit much harsher indoor air environments than the design set point. This has resulted in component failure due to corrosion of metallurgy via a corrosive gas environment.

Attempts to mitigate these failures have focused on the use of commercially available conformal coatings. These conformal coatings fall into one of several generic classes: silicones, epoxies, acrylates, or other organic materials. However, accelerated aging testing has revealed that silicones may actually exacerbate the problem and that corrosion is merely retarded by the other classes of conformal coatings. Furthermore, studies have revealed that the major culprit in the gaseous environment is elemental sulfur, H₂S, or sulfur oxides. Of these, elemental sulfur appears to be the most aggressive.

In High Current (HC) circuits, available conformal coatings have been found to be detrimental. Due to the high heat in HC circuits, conformal coatings end up interfering with the dispersion of that heat.

A need exists for a method and structure for implementing a conformal coating composition for high current applications.

### SUMMARY OF THE INVENTION

Principal aspects of the present invention are to provide a method and structure for implementing a conformal coating composition for high current applications. Other important aspects of the present invention are to provide such method and structure substantially without negative effects and that overcome many of the disadvantages of prior art arrangements.

In brief, a method and structure are provided for implementing a conformal coating composition for high current applications. A copper particulate filler material layer is added over a standard conformal coating layer of a circuit component. The added layer aids in dispersing the heat away from the circuit component. The copper particulate filler material reacts with sulfur bearing gasses and prevents corrosive agents from reacting with the underlying component metallurgy, thus extending the product life.

In accordance with features of the invention, the copper particulate filler material layer provides top layer conformal coating for high current applications. A base layer includes a standard silicone conformal coating. The base layer is first applied to a circuit component, such as resistors and allowed to partially cure, such as about 10-15 minutes, prior to adding the metal particulate containing silicone conformal coating overtop the base layer.

In accordance with features of the invention, the copper particulate filler material layer is formed with a filler-free silicone conformal coating, >10 wt % copper particulate (<75 microns) is added and blended via high speed dispersion mixing. The newly blended conformal coating is then degassed under vacuum to remove entrapped air. After degassing, the conformal coating is applied to a circuit component ensuring that no air bubbles are present. The coating is allowed to cure for 24 hours before use.

In accordance with features of the invention, the circuit is ready for use after curing for about 24 hours at room temperature. The copper particulate conformal coating serves to disperse the heat and getter sulfur bearing gas components in order to protect the underlying circuitry.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is a flow chart illustrating exemplary steps for manufacturing a conformal coating composition for high current applications in accordance with the preferred embodiment;

FIG. 2 is a flow chart illustrating example steps for implementing a structure embodying the conformal coating composition for high current applications in accordance with the preferred embodiment.

### DETAILED DESCRIPTION OF THE PREFERRED EMBODIMENTS

In the following detailed description of embodiments of the invention, reference is made to the accompanying drawings, which illustrate example embodiments by which the invention may be practiced. It is to be understood that other embodiments may be utilized and structural changes may be made without departing from the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In accordance with features of the invention, a method and structure are provided for implementing a conformal coating composition for high current applications. A copper particulate conformal coating serves to disperse the heat and getter sulfur bearing gas components in order to protect the underlying circuitry in accordance with preferred embodiments.

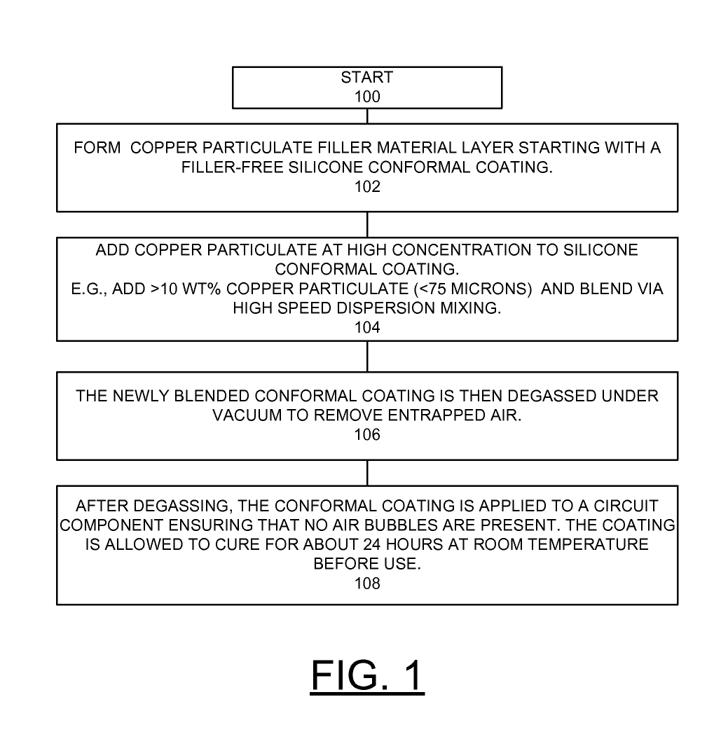

Having reference now to the drawings, in FIG. 1, there is shown a flow chart illustrating example steps generally designated by reference character 100 for manufacturing a conformal coating composition for high current applications in accordance with the preferred embodiment starting at a block 100.

As indicated at a block 102, a copper particulate filler material layer is formed starting with a filler-free silicone conformal coating.

As indicated at a block 104, copper particulate is added to the filler-free silicone conformal coating and blended via high speed dispersion mixing. For example, copper particulate (>percolation threshold) is blended with Dow Corning 1-2620. Copper particulate, such as >10 wt % copper particulate (<75 microns) is added and blended via high speed dispersion mixing.

As indicated at a block 106, the newly blended conformal coating is then degassed under vacuum to remove entrapped air. After degassing, the conformal coating is applied to a circuit component ensuring that no air bubbles are present as indicated in a block 108. The coating is allowed to cure for 24 hours before use.

In accordance with features of the invention, the copper particulate prevent the corrosion species from ever reaching the metallurgy on the component by reacting with the sulfur to form Cu₂S at room temperature, thus eliminating possible corrosion. Similar to a heat sink when the conformal coating composition for high current applications in accordance with the preferred embodiment is applied on top of a standard conformal coating, the copper will help to disperse the heat away from the High Current (HC) circuit components due to its high thermal conductivity.

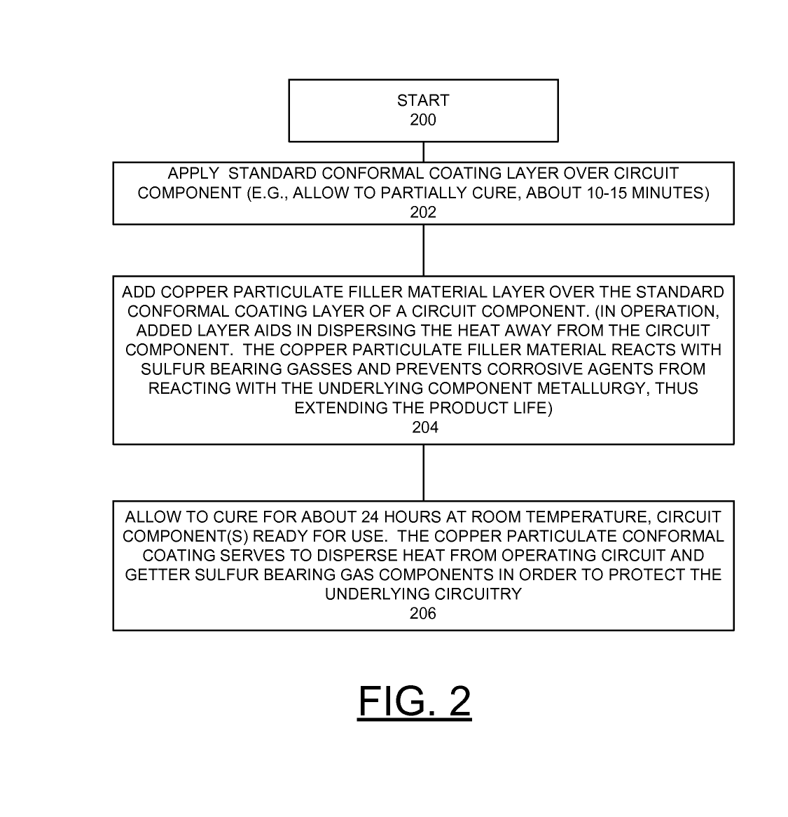

Referring to FIG. 2, there are shown example steps for implementing a structure embodying the conformal coating composition for high current applications in accordance with the preferred embodiment.

As indicated in a block 202, a standard conformal coating layer is applied over a circuit component. The standard conformal coating layer is allowed to partially cure, such as about 10-15 minutes prior to adding the metal particulate containing silicone conformal coating overtop the base layer.

As indicated in a block 204, the copper particulate filler material layer is added over a standard conformal coating layer of a circuit component. The added layer aids in dispersing the heat away from the circuit component. The copper particulate filler material reacts with sulfur bearing gasses and prevents corrosive agents from reacting with the underlying component metallurgy, thus extending the product life.

While the present invention has been described with reference to the details of the embodiments of the invention shown in the drawing, these details are not intended to limit the scope of the invention as claimed in the appended claims.

1. A method for implementing a conformal coating composition for high current applications comprising:
providing a first conformal coating layer on a circuit component;
forming the conformal coating composition with a copper particulate filler material layer;
adding the copper particulate filler material layer over the standard conformal coating layer on the circuit component; and
allowing the added copper particulate filler material layer to cure for a predefined time period.

2. The method as recited in claim 1 wherein forming the conformal coating composition with a copper particulate filler material layer includes providing a filler-free silicone conformal coating and adding copper particulate as a filler material.

3. The method as recited in claim 2 wherein adding copper particulate as a filler material includes adding about 10 weight percent (wt %) copper particulate of less than 75 microns.

4. The method as recited in claim 2 further includes blending via high speed dispersion mixing.

5. The method as recited in claim 4 further includes degassing the newly blended conformal coating under vacuum to remove entrapped air.

6. The method as recited in claim 5 wherein adding the copper particulate filler material layer over the standard conformal coating layer on the circuit component includes after degassing applying the blended conformal coating to the circuit component ensuring that no air bubbles are present.

7. The method as recited in claim 1 wherein allowing the added copper particulate filler material layer to cure for a predefined time period includes allowing the added copper particulate filler material layer to cure for about 24 hours before use.

8. The method as recited in claim 1 wherein providing a standard conformal coating layer on a circuit component includes allowing the standard conformal coating layer on a circuit component to partially cure before adding the copper particulate filler material layer over the standard conformal coating layer on the circuit component.

9. The method as recited in claim 1 wherein allowing the standard conformal coating layer on a circuit component to partially cure includes allowing the standard conformal coating layer on a circuit component to partially cure in a range between 10 and 15 minutes.

10. The method as recited in claim 1 wherein the added copper particulate filler material layer reacts with sulfur bearing gasses and prevents corrosive agents from reacting with the underlying component metallurgy.

11. The method as recited in claim 1 wherein the added copper particulate filler material layer coating serves to disperse heat and getter sulfur bearing gas components protecting the underlying circuitry.

12. The method as recited in claim 1 wherein providing the first conformal coating layer on a circuit component includes providing a standard conformal coating layer on a circuit component.

13. A circuit structure produced by a method as recited in claim 1.

14-19. (canceled)
